(19) United States
(12) Patent Application Publication
(10) Pub. No.: US 2026/0354112 A1
(43) Pub. Date: Nov. 5, 2026

(54) PRECISION Z-STAGE WITH NANOMETER STEP SIZE

(71) Applicant: Applied Materials, Inc., Santa Clara, CA (US)

(72) Inventor: Bernhard STONAS, Hayward, CA (US)

(21) Appl. No.: 19/101,737

(22) PCT Filed: Aug. 23, 2023
(86) PCT No.: PCT/US2023/030914

§ 371 Date: Feb. 6, 2025

Related U.S. Application Data
(60) Provisional application No. 63/373,317, filed on Aug. 23, 2022.

(51) Int. Cl. H10P 72/76

(52) U.S. Cl. CPC H10P 72/7624; H10P 72/7618

(57) ABSTRACT

The present disclosure is directed to a stage for supporting a substrate. The stage includes a rotating base having a top surface with a rotating base flatness of 1 nm or less, a motor, a screw disposed on the rotating base, a nut threadably connected to the screw, one or more stabilization arms, and a substrate support disposed on the nut. The rotating base flatness of the top surface of the rotating base is a difference between a maximum point and a minimum point on the top surface of the rotating base. The screw has a bottom surface with a screw flatness of 1 nm or less. The flatness of the screw is the difference between a maximum point and a minimum point on the bottom surface of the screw. The motor rotates the rotating base and the screw.

### BACKGROUND

### FIELD

Embodiments of the present disclosure generally relate to substrate processing and metrology apparatuses. More particularly, embodiments of the present disclosure relate to Z-axis stages within substrate processing and metrology apparatuses.

### Description of the Related Art

In the manufacture of solar panels, flat panel displays, and other semiconductor devices, many processes are employed to deposit thin films on substrates, such as semiconductor substrates, solar panel substrates, and liquid crystal display (LCD) and/or organic light emitting diode (OLED) substrates, to form electronic devices thereon. The deposition is generally accomplished by introducing a precursor gas into a chamber having a substrate disposed on a temperature controlled substrate support. The precursor gas is typically directed through a gas distribution assembly disposed above the substrate support. The precursor gas in the chamber is energized (e.g., excited) into a plasma by applying a single or array of radio frequency (RF) antennas inductively coupled to the precursor gas to form the plasma. The excited gas reacts to form a layer of material on a surface of the substrate that is positioned on the temperature controlled substrate support.

The uniformity and accuracy of the deposition of the thin films in thin film applications are critical. The ability to move the substrate support during processing and metrology at nano-scale distances is required to perform these functions. Current technologies may offer the ability to move at these scales, but tend to have smaller throw distances (i.e., distance in the Z-axis direction between the highest point and the lower point). Typically, this is due to the utilization of piezoelectric crystals for moving the substrate along the Z-axis, which, while very precise, has a limited throw distance. Meanwhile, Z-axis stages with the capacity for larger throw distances are less precise when it comes to nano-scale movements.

Accordingly, what is needed in the art are systems and apparatuses for increased throw distance of Z-axis stages with improved step-size precision.

### SUMMARY

Embodiments of the present disclosure generally relate to substrate processing and metrology apparatuses. More particularly, embodiments of the present disclosure relate to Z-axis stages within substrate processing and metrology apparatuses.

In one embodiments, a stage for supporting a substrate is disclosed. The stage includes a rotating base having a top surface with a flatness of 1 nm or less, a motor, a screw disposed on the rotating base, a nut threadably connected to the screw, one or more stabilization arms, and a substrate support disposed on the nut. The flatness of the top surface of the rotating base is a difference between a maximum point on the top surface of the rotating base and a minimum point on the top surface of the rotating base. The screw has a bottom surface with a flatness of 1 nm or less. The flatness of the screw is the difference between a maximum point on the bottom surface and a minimum point on the bottom surface of the screw. The rotating base rotates the screw. The motor rotates the rotating base.

In another embodiment, a controller of a stage storing instructions is disclosed. The instructions, when executed by a processor, cause the stage to move a substrate disposed on the stage along a Z-axis. The stage further includes a plurality of sensors to measure a position of the substrate along the Z-axis, adjust a motor speed to position the substrate along the Z-axis, control a temperature of the stage during processing and measuring, and control an electric field produced by the stage.

In another embodiment, a processing system suitable for semiconductor processing is disclosed. The processing system includes a rotating base having a top surface with a flatness of 1 nm or less, a motor, a screw disposed on the rotating base, a nut threadably connected to the screw, one or more stabilization arms, and a substrate support disposed on the nut. Flatness is a difference between a maximum point on the top surface and a minimum point on the top surface of the rotating base. The motor rotates the rotating base. The screw has a bottom surface with a flatness of 1 nm or less. Flatness is the difference between a maximum point on the bottom surface and a minimum point on the bottom surface of the screw. The rotating base rotates the screw.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, and may admit to other equally effective embodiments.

FIG. 1 is a schematic perspective view of a z-stage, according to embodiments of the disclosure.

FIG. 2 is a schematic top plan view of the z-stage, according to embodiments of the disclosure.

FIG. 3 is a schematic cross-sectional side view of the z-stage 100 at a cut line A-A, according to embodiments of the disclosure.

FIG. 4 is a schematic perspective view of a nut and a screw of the z-stage, according to embodiments of the disclosure.

FIG. 5 is a schematic top plan view of the nut and the screw of the z-stage, according to embodiments of the disclosure.

FIG. 6 is a control schematic for use within the z-stage of FIG. 1, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to systems and apparatuses for substrate processing and metrology. More particularly, embodiments of the present disclosure relate to Z-axis stages within substrate processing and metrology apparatuses.

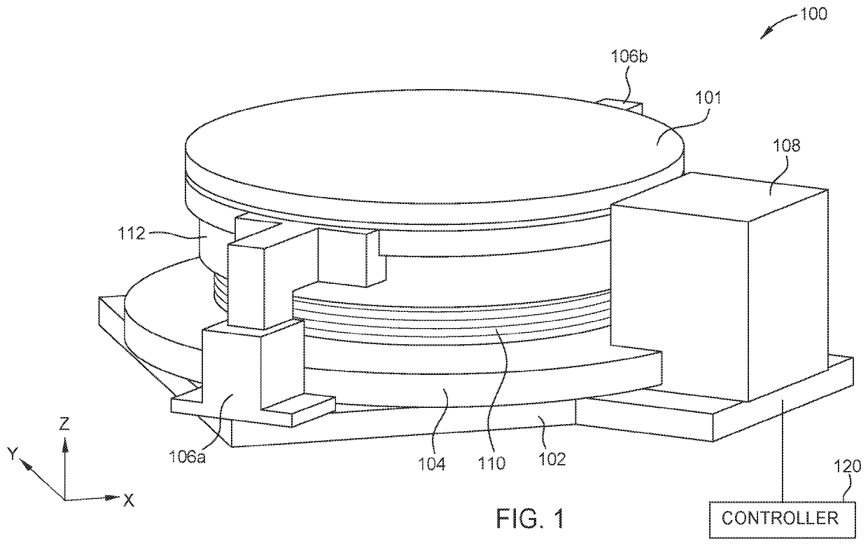

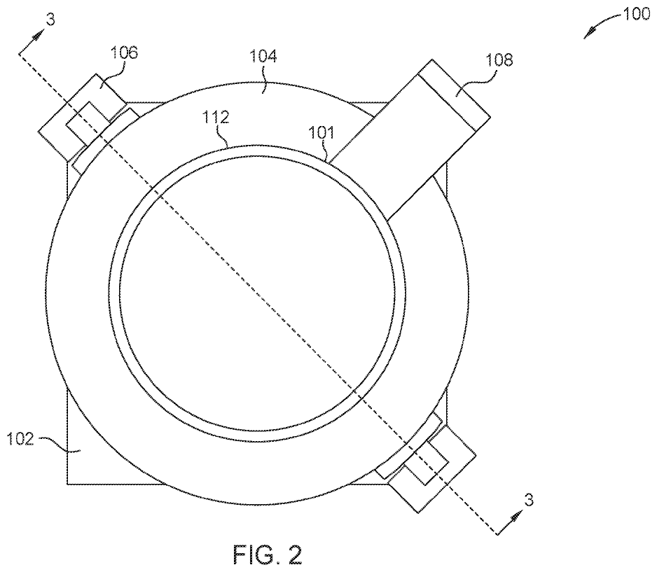

FIG. 1 is a schematic perspective view of a Z-axis stage (e.g., z-stage 100). FIG. 2 is a schematic top plan view of the z-stage 100. The z-stage is configured to support a substrate and move the substrate along the Z-axis. The z-stage 100 includes a cooling base 102, a rotating base 104, one or more stabilization arms 106, a motor 108, a screw 110, and a nut 112. The nut 112 supports a substrate support 101 on the z-stage 100. The substrate support 101 supports a substrate within the z-stage system. The stabilization arms 106 position the screw 110 and nut 112 in the X- and Y-axis. In the illustrated embodiment, a first stabilization arm 106a and a second stabilization arm 106b are shown spaced 180° apart. However, other embodiments are contemplated by this disclosure, e.g., three stabilization arms 106 spaced 120° apart or four stabilization arms 106 spaced 90° apart. In one embodiment, the stabilization arms 106 include voice coil motors to position the screw 110 and nut 112 in the X- and Y-axis. As the nut 112 translates along the Z-axis, the voice coil motors maintain the screw 110 and nut 112 in the same position along the X- and Y-axis using an electric field produced by electromagnets in the voice coil motors. The use of electromagnetic voice coil motors allows for increased accuracy in the positioning of the screw 110 and the nut 112 in the X- and Y-axis., e.g., located with sub-nanometer precision such as +/−1 μm.

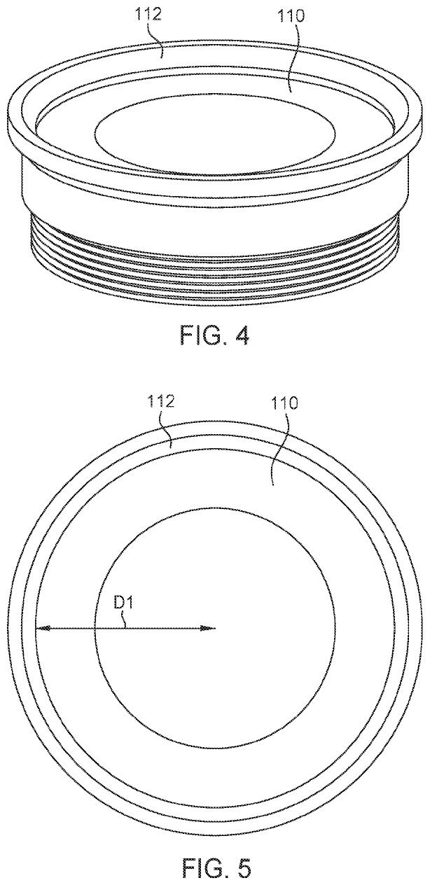

The motor 108 rotates the rotating base 104, which in turn causes rotation of the screw 110. The screw 110 is threadably connected to the nut 112. As the motor 108 turns the screw 110, the threaded connections cause the nut 112 to move upward or downward along the Z-axis, depending on the direction of rotation. In one embodiment, the distance between the top most position along the Z-axis and bottom most position along the Z-axis (e.g., the throw distance) is between about 15 mm and about 50 mm, such as 20 mm. The threading between the screw 110 and the nut 112 has a pitch of about 0.25 mm to 0.75 mm, such as about 0.5 mm. As shown in FIG. 4 and FIG. 5, the diameter D1 of the outside edge of the screw 110 (as well as the inside edge of the nut 112) is between about 100 mm and about 200 mm, e.g., about 150 mm. The step-size of the z-stage 100, e.g., the incremental distances that the z-stage 100 can move within the Z-axis, is between about 1 nm and about 50 nm. The motor 108, diameter D1 of the outside edge of the screw, and pitch of the threaded connection control the distance that the nut 112 moves along the Z-axis. The combination of nanometer step sizes with large throw distances allows for enhanced processing and/or metrology of the substrate.

The z-stage 100 further includes a controller 120. The controller 120 is in direct or indirect communication with the z-stage 100 and is used to control processes of the z-stage 100. The z-stage 100 includes a plurality of sensors (not shown) disposed therein for measuring parameters such as motor speed, Z-axis movement, and electrical field of the stabilization arms 106. For example, the position of the substrate along the Z-axis is measured with increased accuracy through the use of a linear encoder positioned on the screw 110 or the nut 112. The readings from the linear encoder are utilized by the controller 120 to dictate the speed of the motor 108.

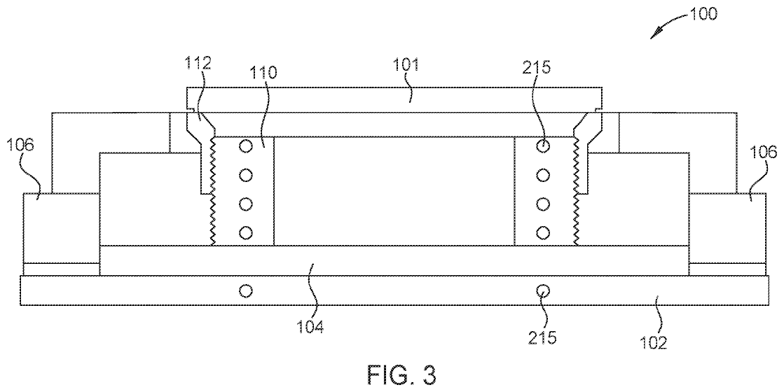

FIG. 3 is a schematic cross-sectional side view of the z-stage 100 at a cut line A-A of FIG. 2. As shown, the screw 110 is disposed on the rotating base 104. The rotating base 104 is rotated by the motor 108, which in turn rotates the screw 110 within the nut 112. This rotation drives the nut 112 up or down along the Z-axis, depending on the direction of the rotation. The rotating base 104 has a top surface flatness in the nanometer range, e.g., a difference between the maximum point on the rotating base 104 and the minimum point on the rotating base 104 is less than about 1 nm. A bottom surface of the screw 110 has a flatness in the nanometer range, e.g., a difference between a maximum point on the bottom surface of the screw 110 and a minimum point on the bottom surface of the screw 110 is less than about 1 nm. This allows the screw 110 and the nut 112 to keep a pitch accuracy of 1 nm. Further, it allows the screw 110 to rotate on the rotating base 104 with a flatness of 1 nm, as well as keeping the nut 112 parallel to the rotating base 104 within 1 nm. The nut 112 being parallel to the rotating base 104 ensures that the processing and metrology being performed on the substrate is accurate and precise. In another embodiment, the rotating base 104 is stationary and the screw 110 rotates on top of the rotating base 104. The motor 108 contacts the screw 110 directly and drives the rotation of the screw 110. The flatness between the rotating base 104 and the screw 110 allows for minimal friction as the screw 110 rotates over the rotating base 104. To achieve a flatness of less than 1 nm, the screw 110 and the rotating base 104 may be manufactured using a water-cooled grinding process. The water-cooled grind process allows for control of the temperature of the screw 110 and the rotating base 104 during the grinding process, which prevents temperature warping of the materials as the rotation is performed. Controlling temperature warping during the rotation allows for the rotation to achieve the nano-scale accuracies needed in the z-stage 100.

In certain embodiments, the screw 110 and the cooling base 102 may each contain a plurality of cooling conduits 215. The cooling conduits circulate a cooling fluid (e.g., water, air, or other liquid or gaseous coolants) through the z-stage to reduce the amount of heat generated from friction between the screw 110 and the rotating base 104. Due to the nano-scale movements of the substrate support 101 in the Z-axis, there is a need to control the temperature of the z-stage 100 so that the measurements of the z-stage sensors are accurate.

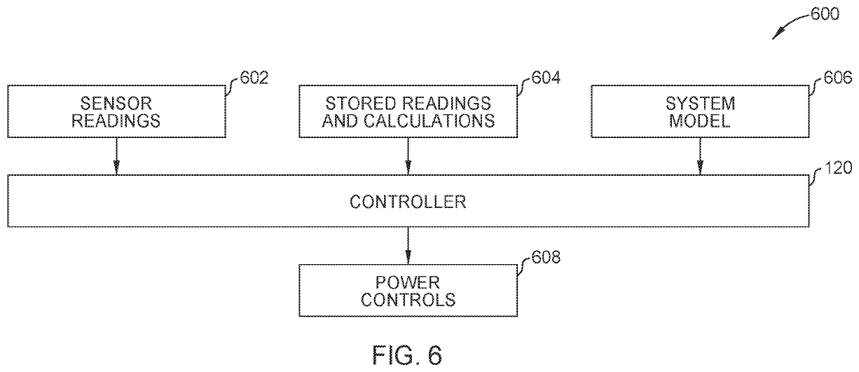

FIG. 6 is a control schematic 600 for use within the z-stage 100. The controller 120 is part of the z-stage for storing instructions that, when executed, cause the z-stage to adjust a position of a substrate on the z-stage for processing or measuring, according to embodiments of this disclosure. The instructions may, in certain embodiments, also cause the processing or measuring of the substrate on the z-stage (e.g., by a processing device or metrology device) while the substrate moves along the Z-axis. In one embodiment, the instructions cause the z-stage to move the substrate support 101 to a position along the z-axis direction according to a deposition or metrology process. The z-stage 100 includes a plurality of sensors to measure the z-axis position, motor speed, and stabilization arm electrical field. The controller 120 receives data or input from sensor readings 602 from the sensors of the z-stage 100. The controller 120 is equipped with or in communication with a system model 606 of the z-stage 100. The system model 606 includes motor modules and power modules. The system model 606 is a program configured to estimate the motor speed and stabilization arm electrical field power within the z-stage 100 throughout the process. The controller 120 is further configured to store readings and calculations 604.

The readings and calculations 604 include previous sensor readings 602, as well as any other previous sensor readings within the z-stage 100. The readings and calculations 604 further include the stored calculated values from after the sensor readings 602 are measured by the controller 120 and run through the system model 606. Therefore, the controller 120 is configured to both retrieve stored readings and calculations 604 as well as save readings and calculations 604 for future use. Maintaining previous readings and calculations enables the controller 120 to adjust the system model 606 over time to reflect a more accurate version of the z-stage 100.

In embodiments described herein, the controller 120 includes a programmable central processing unit (CPU) that is operated with a memory and a mass storage device, an input control unit, and a display unit (not shown). The controller 120 monitors the motor speed, stabilization arm electrical field, and z-axis position. Support circuits are coupled to the CPU for supporting the processor in a conventional manner. In some embodiments, the controller 120 includes multiple controllers 120, such that the stored readings and calculations 604 and the system model 606 are stored within a separate controller from the controller 120 which operatres the z-stage 100. In other embodiments, all of the system model 606 and the stored readings and calculations 604 are saved within the controller 120. The controller 120 is configured to control the motor speed, stabilization arm electrical field, and z-axis position through the z-stage 100 by controlling aspects of the power controls 608.

The controller 120 is configured to adjust the motor speed, electrical field, and Z-axis position of the power controls 608 based off the sensor readings 602, the system model 606, and the stored readings and calculations 604. The controller 120 includes embedded software and a compensation algorithm to calibrate the Z-axis position of the substrate. The Z-axis position of the substrate may be measured as the substrate support 101 moves along the Z-axis process operations to provide a reference for the Z-axis position measured using the sensors. In various embodiments, the controller 120 may include a machine-learning algorithm and may use a regression or clustering technique. The algorithm may be an unsupervised or a supervised algorithm.

While the foregoing is directed to embodiments of the present disclosure, other and further embodiments of the disclosure may be devised without departing from the basic scope thereof, and the scope thereof is determined by the claims that follow.

What is claimed is:

1. A stage for supporting a substrate, the stage comprising:
a rotating base having an top surface with a rotating base flatness of 1 nm or less, wherein the rotating base flatness is a difference between a maximum point on the top surface and a minimum point on the top surface of the rotating base;
a motor, wherein the motor rotates the rotating base;
a screw disposed on the rotating base, the screw having a bottom surface with a screw flatness of 1 nm or less, wherein the screw flatness is the difference between a maximum point on the bottom surface and a minimum point on the bottom surface of the screw, and wherein the rotating base rotates the screw;
a nut threadably connected to the screw;
one or more stabilization arms; and
a substrate support disposed on the nut.

2. The stage of claim 1, wherein the threadable connection between the threadably connected screw and nut has a diameter between 100 nm and 200 nm, a pitch between 0.25 mm and 0.75 mm, and a step size of between 1 nm and 100 nm.

3. The stage of claim 1, wherein the threadable connection between the screw and the nut has a throw of about 15 nm to about 50 nm.

4. The stage of claim 1, wherein the nut is in parallel with the rotating base within +/−1 nm.

5. The stage of claim 1, wherein the stabilization arms position the screw and the nut in a X- and a Y-axis using an electrical field.

6. The stage of claim 5, wherein the electrical field of the stabilization arms is produced using a plurality of voice coil motors.

7. The stage of claim 1, wherein the screw and the rotating base are fabricated to a flatness of 1 nm or less using a water-cooled grind process.

8. The stage of claim 1, further comprising a linear encoder.

9. The stage of claim 1, wherein the screw and the rotating base include a plurality of cooling channels.

10. A controller of a stage storing instructions that, when executed by a processor, causes the stage to:
move a substrate disposed on the stage along a Z-axis, wherein the stage further comprises a plurality of sensors to:
measure a position of the substrate along the Z-axis;
adjust a motor speed to position the substrate along the Z-axis;
control a temperature of the stage during processing and measuring; and
control an electric field produced by the stage.

11. The controller of claim 10, wherein the stage comprises:
a rotating base having a top surface with a rotating base flatness of 1 nm or less, wherein the rotating base flatness is a difference between a maximum point on the top surface and a minimum point on the top surface of the rotating base;
a motor, wherein the motor rotates the rotating base;
a screw disposed on the rotating base, the screw having a bottom surface with a screw flatness of 1 nm or less, wherein the screw flatness is the difference between a maximum point on the bottom surface and a minimum point on the bottom surface of the screw, and wherein the rotating base rotates the screw;
a nut threadably connected to the screw;
one or more stabilization arms; and
a substrate support disposed on the nut.

12. The stage of claim 11, wherein a threadable connection between the threadably connected screw and nut has a diameter between 100 nm and 200 nm, a pitch between 0.25 mm and 0.75 mm, and a step size of between 1 nm and 100 nm.

13. The stage of claim 11, wherein the threadable connection between the screw and the nut has a throw of about 15 nm to about 50 nm.

14. The stage of claim 11, wherein the nut is in parallel with the rotating base within +/−1 nm.

15. The stage of claim 11, wherein the stabilization arms position the screw and the nut in a X- and a Y-axis using an electrical field.

16. The stage of claim 15, wherein the electrical field of the stabilization arms is produced using a plurality of voice coil motors.

17. The stage of claim 11, wherein the screw and the rotating base are fabricated to a flatness of 1 nm or less using a water-cooled grind process.

18. The stage of claim 11, further comprising a linear encoder.

19. The stage of claim 11, wherein the screw and the rotating base include a plurality of cooling channels.

20. A semiconductor processing system, comprising:
a rotating base having a top surface with a rotating base flatness of 1 nm or less, wherein the rotating base flatness is a difference between a maximum point on the top surface and a minimum point on the top surface of the rotating base;
a motor, wherein the motor rotates the rotating base;
a screw disposed on the rotating base, the screw having a bottom surface with a screw flatness of 1 nm or less, wherein the screw flatness is the difference between a maximum point on the bottom surface and a minimum point on the bottom surface of the screw, and wherein the rotating base rotates the screw;
a nut threadably connected to the screw;
one or more stabilization arms; and
a substrate support disposed on the nut.
